(19) United States
(12) Patent Application Publication
(10) Pub. No.: US 2010/0301353 A1
(43) Pub. Date: Dec. 2, 2010

(54) LED LIGHTING DEVICE HAVING A CONVERSION REFLECTOR

(75) Inventors: Wolfgang Pabst, Deisenhofen (DE); Ralph Bertram, Nittendorf (DE); Martin Zachau, Newton, MA (US); Dirk Berben, Taufkirchen (DE)

Correspondence Address: Viering, Jentschura & Partner - OSR, 3770 Highland Ave., Suite 203, Manhattan Beach, CA, 90266, US

(73) Assignee: OSRAM GESELLSCHAFT MIT BESCHRAENKTER HAFTUNG, Muenchen (DE)

(21) Appl. No.: 12/744,701

(22) PCT Filed: Nov. 26, 2008
(86) PCT No.: PCT/EP2008/010026

§ 371 Date: May 26, 2010

(30) Foreign Application Priority Data
Nov. 26, 2007 (DE) 102007056874.8

(51) Int. Cl. H01L 33/50; H01L 33/60; H01L 33/48

(52) U.S. Cl. 257/88; 257/98; 257/E33.061; 257/E33.056; 257/E33.067

(57) ABSTRACT

An LED lighting device is provided which may include at least one light-emitting diode and at least one conversion reflector, wherein the conversion reflector is configured to emit at least a portion of light emitted from the light-emitting diode at a converted wavelength, and wherein the conversion reflector covers the at least one light-emitting diode.

The invention relates to an LED lighting device which has at least one light-emitting diode and one reflector.

Until now, blue LED light has been converted to white light but the use of a wavelength-conversion material (fluorescent dye, fluorescent substance, for example cerium-doped yttrium-aluminum-garnet powder), which is brought close to the blue light-emitting diode (LED), for example by means of a coating or by encapsulating the blue LED in embedding material containing a fluorescent substance (LED chip). This results in the problem that the conversion efficiency of the wavelength-conversion material falls because of the proximity to the LED, which represents a considerable heat source.

Furthermore when using such LED chips in retrofit lamps (that is to say LED lamps which are similar to the shape and contour and/or emission sensitivity of conventional incandescent lamps), efficiency-reducing measures must be adopted, for example by using diffusers, in order to adapt the external appearance and the light characteristic.

The object of the present invention is therefore to provide a capability to improve a conversion efficiency and therefore the lamp power, in particular for a retrofit lamp.

This object is achieved by means of a lighting device as claimed in claim 1. Advantageous refinements can be found in particular in the dependent claims.

The lighting device has at least one light-emitting diode and at least one reflector, wherein the reflector converts the wavelength of at least a portion of the light emitted from the light-emitting diode, and emits it—typically diffusely (“conversion reflector”).

Since the fluorescent substance is now no longer incorporated in the individual LED or the LED chip, and the conversion volume is no longer in direct contact with the raw LED, but is at a distance from the thermally highly loaded close proximity to the light-emitting diodes and the LED chips, this results in a considerable gain in conversion efficiency. This furthermore makes it possible to use fluorescent substances which are sensitive to ageing or saturate at low power densities such as fluorescent substances doped with Mn²⁺, Mn⁴⁺, Eu³⁺ or Tb³⁺, which are not suitable for use in an LED chip.

In order to effectively dissipate heat from wavelength-conversion material which may be heated considerably by the so-called Stokes shift during the conversion process, in some circumstances, the basic material of the conversion reflector includes a highly thermoconductive material, for example composed of metal or thermally conductive ceramic. The thermal conductivity is preferably more than 15 W/(m·K), and in particular more than 100 W/(m·K).

A reflector area of the at least one conversion reflector preferably has at least one wavelength-conversion material (fluorescent substance) for the light emitted from the at least one light-emitting diode. During wavelength conversion, the converted light is typically emitted isotropically on average.

For example in the case of wavelength conversion between light which is in each case visible, such as blue-yellow conversion, it may be advantageous for a portion of the light emitted from the light-emitting diode to be emitted and reflected again without wavelength conversion. The desired mixed light can thus be achieved comparatively easily, in particular a white mixed light, although in principle the color is not restricted to this.

In order to achieve uniform light emission, the conversion reflector also emits the portion of the light emitted from the light-emitting diode diffusely, or reflects this diffusely, and this portion is not subject to wavelength conversion (if provided). The conversion reflector therefore acts as a diffuser or conversion diffuser, but without any loss of efficiency.

For this purpose, by way of example, the conversion reflector can be designed such that it has a conventional reflective, for example mirror, surface (“reflection surface”), to which a fluorescent layer of suitable concentration and thickness (“conversion layer”) is applied. That portion of the blue primary light which is only reflected then, in one configuration, runs without conversion through the conversion layer to the reflection surface, where it is reflected and subsequently passes back again through the conversion layer without conversion. By way of example, the conversion layer may be formed from an embedding material or matrix material such as silicone resin interspersed with fluorescent material and possibly scattering material. The converted portion of the light is typically emitted isotropically diffusely. The embedding material may also have a phosphorescent substance in order to reduce light ripple, which has a longer relaxation time than the wavelength-conversion material; a phosphorescence time (3 dB time) of about 5-15 ms is preferable in this case.

However, in order to achieve a light color which is uniform over the solid angles, it is preferable for the light whose wavelength has not been converted (if present) to also be diffusely emitted and reflected on the reflector. By way of example, this can be done by a suitable configuration of the reflection surface or by means of a light-scattering characteristic of the conversion layer, typically by means of a light-scattering characteristic of luminescent fluorescent particles or inert particles (for example metal oxides such as SiO₂, Al₂O₃, TiO₂ or ZrO₂) embedded in a matrix (for example silicone). In the case of the—generally isotropic—scattering of the blue light by the fluorescent particles, use is made of the effect that a conversion level is not complete, but a portion of the primary light striking a fluorescent particle is admittedly absorbed, but is emitted again without wavelength conversion. Typical embedding and matrix materials which do not themselves scatter or scatter only insignificantly comprise silicone, epoxy resin or the like. However, it is also possible to use a scattering embedding material or matrix material, for example a non-transparent plastic such as sintered Teflon.

If the conversion layer also scatters the primary light, the length of the light path through the conversion layer can be increased by the reflection surface which is preferably present, by which means the thickness of the conversion layer can be reduced in order to adequately scatter, preferably completely scatter, the primary light in the conversion layer, thus saving expensive fluorescent material. Typical layer thicknesses for a configuration such as this are in the region around 2-50 μm, preferably 10-50 μm, and particularly preferably 30 μm, with the exact value being highly dependent on the fluorescent substance concentration, the absorption coefficient of the fluorescent substance, the quantum efficiency of the fluorescent substance, a desired color, the grain size of the fluorescent substance and a scattering characteristic of the embedding material.

Alternatively, the thickness of the conversion layer may be so great that there is no longer any need for a mirror reflection surface for adequate, in particular complete, scattering without wavelength conversion. Typical layer thicknesses for such a “non-transparent” conversion layer, in which the optical characteristics of the surface of the conversion reflector body no longer play a significant role, are in the range from 10-200 μm, preferably 30-100 μm, with the exact value being highly dependent on the fluorescent substance concentration, the absorption coefficient of the fluorescent substance, the quantum efficiency of the fluorescent substance, a desired color, the grain size of the fluorescent substance and a scattering characteristic of the embedding material. In general, a thick conversion layer has the advantage of greater tolerance to fluctuations in the thickness, and can therefore be produced reproducibly more easily.

The fluorescent substance and therefore the conversion reflector, to be precise its reflector area, in general have a “non-white” body color when using LEDs which emit in the visible range of the spectrum, in particular in the blue range of the spectrum. Even when using LEDs which emit in the ultraviolet range, a “non-white” body color is possible, but not essential.

The light emitted from the at least one conversion reflector preferably results in a white mixed light.

A lighting device is preferred for this purpose, in which the at least one light-emitting diode is a blue-light-emitting diode, and the wavelength-conversion material converts blue light to yellow light. This typically results in a “cold white” with a typical color temperature of about 6500 K. Two wavelength-conversion materials, which convert the blue light from the LED(s) to yellow light or red light, are preferred in order to produce a “warm white” with a typical color temperature of between about 3000 K and 4000 K. The blue component for “cold white” is typically 15%-20%, and that for “warm white” is about 10%-15%.

However, it may also be preferable for the at least one light-emitting diode to be a UV light-emitting diode, and for the wavelength-conversion materials to convert UV light to red, green or blue light, or a color combination with a similar effect. It is then greatly preferable for the UV light to be completely converted to visible mixed light.

In order to improve customer acceptance, particularly for retrofits, it is particularly advantageous for the reflector area or the reflector areas of the conversion reflector, which is typically “non-white”, not to be visible from the outside, at least in a plan view from above (that is to say from the bulb side).

Admittedly, it may be sufficient for the reflector area of the conversion reflector to be visible only when viewed from the side, but it is preferable for it not to be visible from the outside.

Vision protection panels may also be provided, and are arranged such that they prevent direct viewing of the reflector area of the conversion reflector.

For accurate and simple positioning of the conversion reflector, it is advantageous if the conversion reflector is fitted to a substrate (LED module), to which the at least one light-emitting diode is fitted, in the emission direction of the at least one light-emitting diode.

For even more effective thermal decoupling between the conversion reflector and the light-emitting diode or diodes or LED module, it may be advantageous for the conversion reflector to be arranged without any direct contact with the supporting substrate in the emission direction of the light-emitting diode or diodes.

In order to achieve a high beam strength and a good light distribution, it is advantageous if the lighting device has an LED module with a plurality of light-emitting diodes which are fitted on a common substrate.

In order to adjust the emission angle over a wide range, it is advantageous for the conversion reflector to taper in the direction of the LED module.

For this purpose, and in order to avoid a direct view of the light-emitting diode or diodes, it may be advantageous for the conversion reflector to overhand the light-emitting diode or diodes at the side.

For an improved emission characteristic of the lighting device and in order to achieve a more user-friendly appearance, it is particularly preferable for the lighting device furthermore to have a further reflector (without a wavelength-conversion characteristic) on which (white or different-color) mixed light emitted from the conversion reflector falls. This makes it possible to particularly easily conceal the typically “non-white” reflector area which the light source has from being viewed by a user. The user then sees only the further reflector or even further reflectors connected downstream therefrom.

However, a further reflector may also be preferable which contains a fluorescent substance, for example a wavelength-conversion material, in particular a fluorescent coating. A fluorescent substance such as this offers advantages, particularly in the case of fluorescent substance mixtures, for example in the case of warm white or—even more significantly—in the case of UV conversion. The fluorescent substances can then be arranged separately from one another, reducing mutual absorption and thus further improving the efficiency. For use with UV LEDs, no body color occurs at all, since at least the blue-emitting fluorescent substance has no body color (that is to say this fluorescent substance is white).

In order to prevent inadvertent mixing of the mixed light reflected or emitted from the conversion reflector, it is advantageous for the further reflector to be arranged such that the light emitted from the light-emitting diode or the light module does not fall on it directly, but only via the conversion reflector.

For a space-saving arrangement, it is advantageous for the further reflector to be arranged at the side of the light-emitting diode.

In order to reduce inadvertent mixing of the mixed light reflected or emitted from the conversion reflector, with blue light passing by the conversion reflector, it is advantageous for the lighting device to have at least one panel in order to block the light which is emitted from the at least one light-emitting diode and does not fall on the conversion reflector. This panel, these panels or some other panel can also be provided for concealment of the reflector area of the conversion reflector which emits the mixed light. Furthermore, a lighting device is preferable which has a light device with a coupling means which inputs a light emitted from the conversion reflector and leads it to a light area. By way of example, the coupling means may be an optical waveguide, for example a glass fiber or a Plexiglas body. The light area preferably has a phosphorescent substance, which still continues to phosphorize even after the LED lamp has been switched off. Alternatively, it may have a mask in order to mask a light area which is illuminated over an area. The phosphorescent substance preferably has a considerably longer relaxation time than the wavelength-conversion material. The light area is preferably arranged on a side of the conversion reflector facing away from the light-emitting diodes, since this means that a light area of the LED lamp need be reduced only slightly in size.

In order to adjust beam guidance, it is advantageous for the conversion reflector and/or the further reflector to be facetted.

In this case, it is advantageous for a lighting device having a plurality of light-emitting diodes for the conversion reflector to have at least as many facets as light-emitting diodes, and for light from a light-emitting diode to be reflected by means of at least one respectively associated facet.

For simple production, and in particular in order to achieve a retrofit, it is advantageous for the lighting device to furthermore have a bulb, in particular a glass bulb, which is transmissive for the light reflected from the further reflector.

It may be advantageous for the bulb to be at least partially frosted (milky), since this results in a more uniform angle distribution of the light emission.

For particularly simple and compact production, it is advantageous for the further reflector to be formed (externally or internally) on the bulb.

It is furthermore preferable for the further reflector to be in the form of a diffusely scattering reflector, for example by its reflection area being in the form of a frosted reflection area.

If the conversion reflector does not make direct contact with the LED substrate (LED module; LED submount, etc.), it may be advantageous for the lighting device to have an at least partially transparent cover plate, in particular composed of glass, to which the conversion reflector is fitted, for example by adhesive bonding or by being formed integrally.

It is particularly preferable for the LED lamp to be in the form of a retrofit lamp, since a retrofit lamp such as this can have a high luminance density and may have a very similar shape and/or emission characteristics to an incandescent lamp; in particular, the retrofit lamp can be configured such that the primary light sources (LEDs or LED chips) cannot be seen directly. Only the outer bulb can be seen by a viewer.

The invention will be described schematically in more detail with reference to the following exemplary embodiments. In this case, the same elements are provided with the same reference symbols in all the figures.

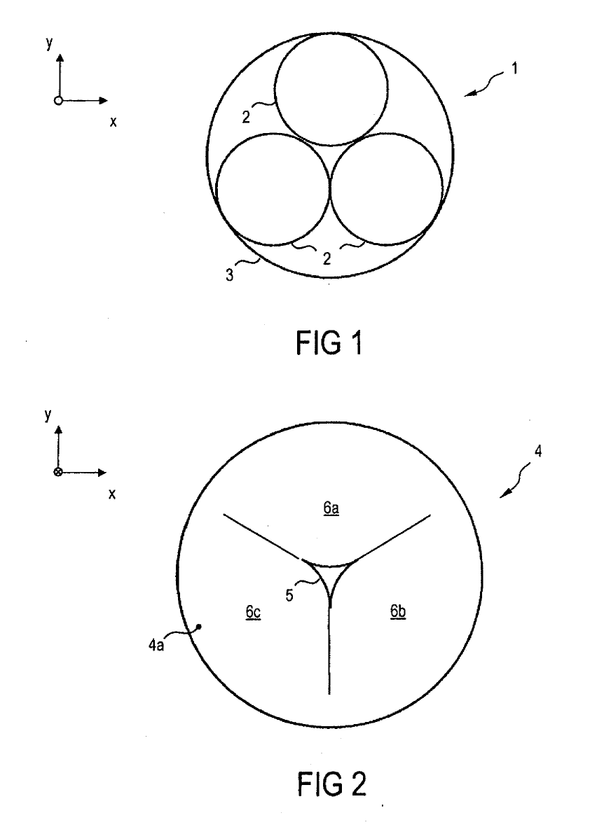

FIG. 1 shows a plan view of an LED module;

FIG. 2 shows a conversion reflector from underneath;

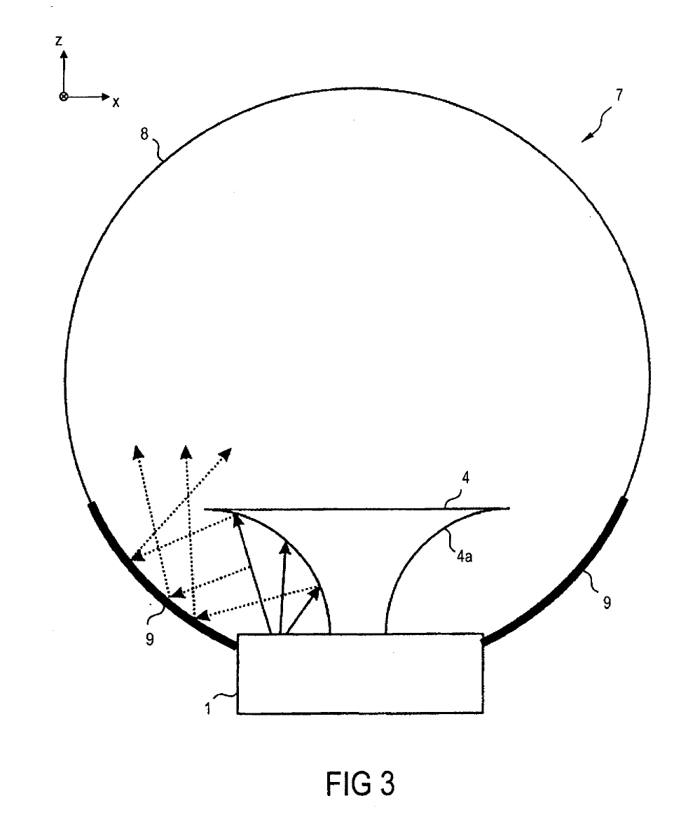

FIG. 3 shows a section illustration, in the form of a side view, of an LED lamp,

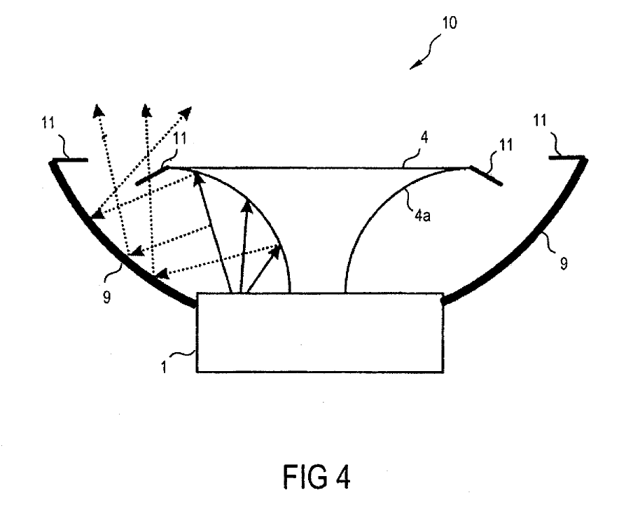

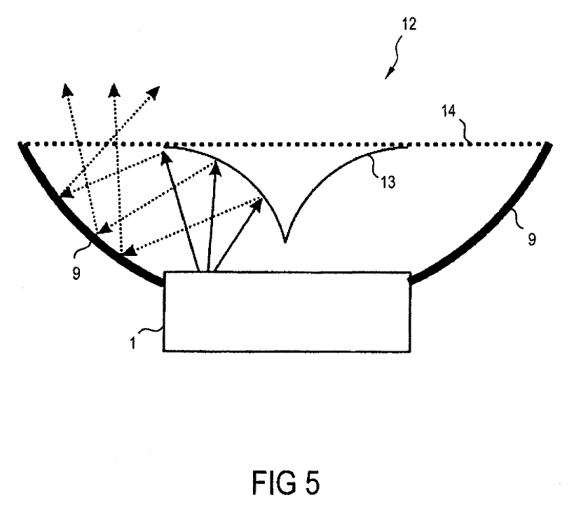

FIG. 4 shows a section illustration, in the form of a side view, of components of a further embodiment of an LED lamp;

FIG. 5 shows a section illustration, in the form of a side view, of yet another embodiment of an LED lamp;

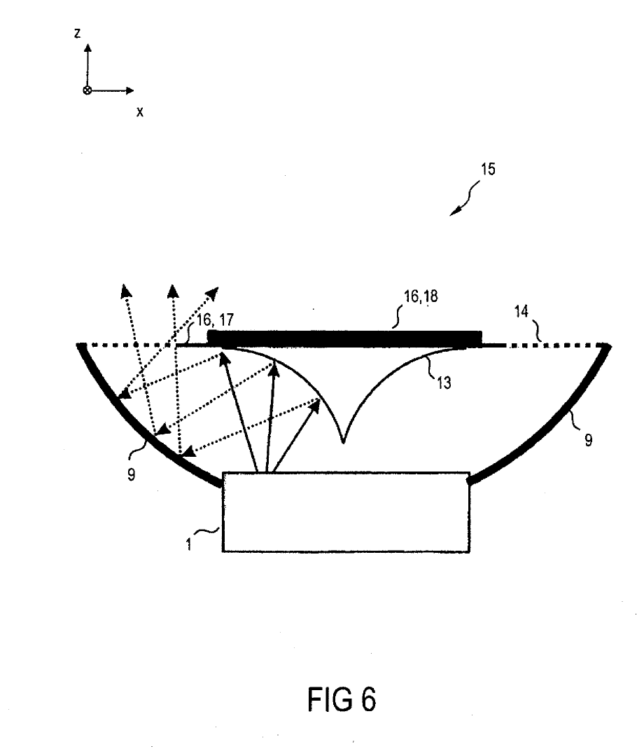

FIG. 6 shows a section illustration, in the form of a side view, of yet another embodiment of an LED lamp;

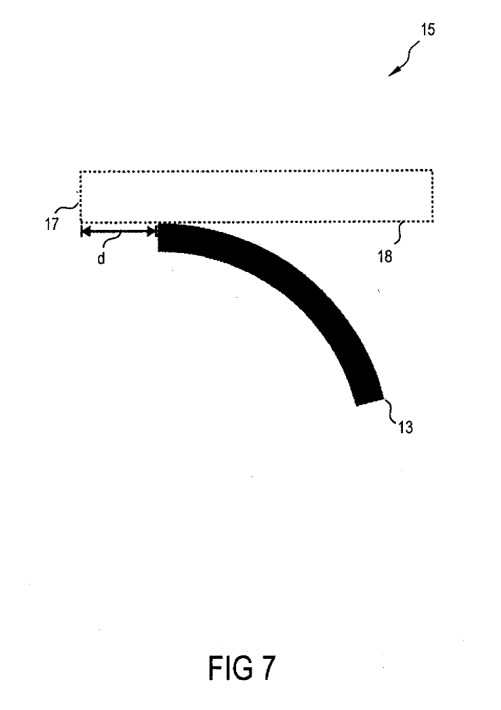

FIG. 7 shows a section illustration, in the form of a side view, of a detail of the LED lamp shown in FIG. 6;

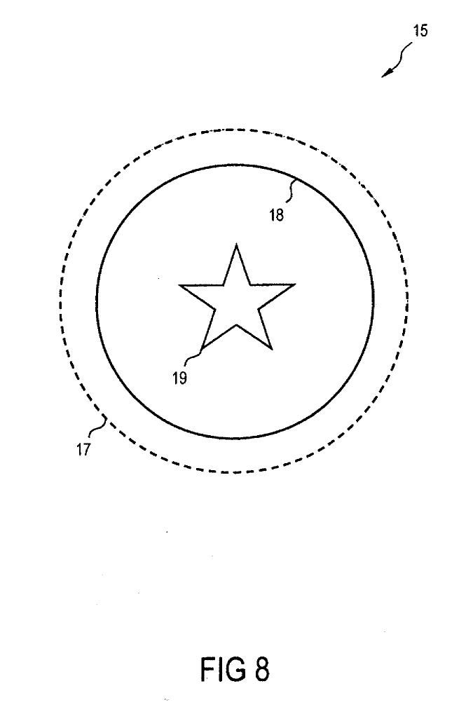

FIG. 8 shows a plan view of a detail of the LED lamp shown in FIG. 6; and

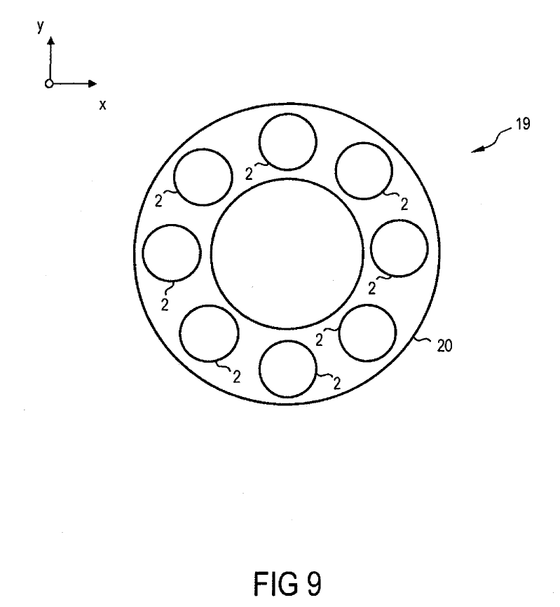

FIG. 9 shows a plan view of a further embodiment of an LED module.

FIG. 1 shows a plan view of an LED module (LED submount) 1, in which three blue-emitting LED chips 2 are arranged on a common substrate 3.

FIG. 2 shows a lower face 4a, which is used as a reflector area, of a conversion reflector 4 composed of plastic, as the basic material. The foot 5 of the conversion reflector 4 fits into the central intermediate space between the LED chips 2 from FIG. 1, and can be fitted to the LED module 1 there. The conversion reflector 4 broadens upward (in the z direction) from the foot 5 and in the process in places forms facets 6a, 6b, 6c. The lower face 4a is designed to be reflective, at least with respect to the light emitted from the LEDs. At least in this reflector area 4a or 6a, 6b, 6c, the conversion reflector 4 furthermore has at least one wavelength-conversion material (fluorescent substance), which converts the blue light from the LED chips to yellow light. The lateral extent (on the x-y plane) is greater than that of the three LED chips.

FIG. 3 shows an LED lamp 7 with the LED module 1 from FIG. 1, and the conversion reflector 4 fitted to it from FIG. 2. The conversion reflector 4 covers the LED module 1 at the side (on the x-y plane), that is to say it projects over it at the side. Furthermore, a lamp bulb 8 composed of glass is provided, fitted to the LED module 1 and surrounding its upper face, which has the LEDs and the conversion reflector 4, which lamp bulb 8 has a further reflector 9, without wavelength-conversion material, on a lower area, adjacent to the LED module 1. The further reflector 9 is arranged at a point on the bulb 7 such that it is not located in the direct emission area of the LED module 1, that is to say does not directly receive its emitted blue light.

In fact, during operation of the lamp 7, the light emitted from the LED module 1 is passed mainly to the lower face 4a of the conversion reflector 4, which acts as a reflector area, as is indicated by the solid arrows. To be more precise, light from each of the LED chips is passed to the respectively facing facet 6a, 6b or 6c. There, the blue light is partially converted to yellow light. The lower face 4a and the facets 6a, 6b, 6c of the conversion reflector 4 is or are shaped such that both unconverted blue light and converted yellow light are directed as white mixed light at the further reflector 9 (dotted arrows), which then reflects the mixed light into the otherwise light-transmissive bulb 8.

A considerable gain in power is achieved by increased conversion efficiency by the removal of the wavelength-conversion material from the thermally highly loaded area around the LEDs and the LED module 1.

The further, second reflector 9 may be both mirrored and diffusely reflective. The further reflector 9 can likewise be facetted. The emission characteristic of a lamp 7 such as this can be matched by suitable faceting of the conversion reflector 4 and/or of the further reflector 9 and/or by so-called “frosting” of the glass bulb 8 to the emission characteristic of any desired lamp. In particular, a lamp 7 such as this is suitable for use as a retrofit lamp; the LED chips and the wavelength-conversion material (fluorescent substance) and the conversion-reflective lower face 4a cannot be seen in plan view.

The lamp shown in FIG. 3 is in the form of a retrofit lamp and, even though this is not shown, in order to improve the clarity, it has suitable electrical connections and drivers for the LED chips 2, and possibly also heat dissipation means. In particular, the lamp 7 may have an Edison cap or a bayonet cap. The contour of the bulb 8 is similar to that of an incandescent lamp.

FIG. 4 shows a detail of a further LED lamp 10, in which now, in contrast to the embodiment shown in FIG. 3, a circumferential panel 11 is in each case provided at the upper edge of the conversion reflector 4 and at the upper edge of the further reflector 9. The panel 11 blocks off that portion of the blue light from the LED module 1 which does not strike the conversion reflector 4. This prevents the white mixed light reflected from the further reflector 9 having an undesirable additional blue-light component added to it, at least at certain viewing angles. Furthermore, the panel 11 is used as concealment of the lower face 4a, which is used as the reflector area of the conversion reflector 4.

FIG. 5 shows a further LED lamp 12, in which the conversion reflector 13 is now no longer placed on the LED module 1 but is attached by its flat upper face to a light-transmissive cover plate 14, for example by adhesive bonding, integral forming or in an integral form. This achieves greater thermal decoupling of the reflector 4 from the LED module 1. The LED lamp 12 now no longer has a completely round bulb as a cover, and in fact the cover plate 14 is used as a top cover. The cover plate 14 can also be in the form of an optical element, for example a Fresnel lens or a microlens array.

FIG. 6 shows yet another LED lamp 15, in which, in comparison to the embodiment shown in FIG. 5, a light device 16 has a coupling means 17 in the form of a glass fiber, which inputs light emitted from the conversion reflector 4 and guides it to a light area 18. In this case, the light area 18 has a phosphorescent substance, which continues to phosphoresce even after the LED lamp has been switched off, and which can be seen from the outside, radiating essentially upward. In this case, the light area 18 is arranged on a side of the conversion reflector 4 facing away from the LED module 1, since a light area of the LED lamp need in this way be reduced only slightly in size, and the light area 18 can be seen well. By way of example, the phosphorescent substance on the light area may be in the form of a Company logo.

FIG. 7 shows the LED lamp 15 in the area of the light input. The coupling means 17 in this case projects at the side in an annular shape over the conversion reflector 13 by a distance d, and inputs the light, which is incident on this annular area with thickness d, into the light area 18. The light area 18 generally emits the input light again, in this case upward with the aid of a phosphorescent substance. Alternatively, by way of example, light can also be emitted at the side in a phosphorescent form or without delay, and can therefore also be seen frequently when viewed from the side when the lamp is switched on, since LED lamps often have a relatively narrow illumination angle range. Coupling means 17 and the light area 18 may be formed integrally, for example as a plate, in which case, for example, the upper surface of the plate can then be coated with a phosphorescent substance.

FIG. 8 shows the light device 16 from above, in which case the light area 18, in this case a symbol 19, for example a Company logo or a brand logo, can phosphoresce.

In a view analogous to FIG. 1, FIG. 9 shows a further embodiment of an LED module 20, in which the LEDs or LED chips 2 are now fitted from an annular substrate 21. The conversion reflector can then be passed through the inner opening and, for example, can be mounted on the cap, thus allowing further thermal decoupling of the conversion material from the heat sources.

The present invention is not, of course, restricted to the described embodiments. For example, the LEDs do not need to emit blue light. More or fewer than three LEDs may be used as light sources. The LEDs may be arranged differently. It is possible to use more than one conversion reflector, and likewise more than one further reflector. Further light-guiding elements may be introduced in the beam path, for example optical lenses or further reflectors or reflector groups. In addition, the shape of the conversion reflector may also be different, for example axially symmetrical even at a short distance from the foot, or it may be completely axially symmetrical. In addition, other wavelength conversion materials as well as light-emitting diodes which emit with a different color may be used, particularly if the colored light emitted from the LED or the LEDs is converted in a general form by the wavelength-conversion materials such that a white or similar mixed light is emitted overall (for example UV-LED and various phosphors as the fluorescent substance on the conversion reflector). In addition, the LED lamp does not need to have a bulb. Furthermore, the bulb does not need to be composed of glass but may have any other suitable light-transmissive material, for example temperature-resistant plastic. In addition, the lamp shape is not restricted.

Furthermore, the light device does not need to emit directionally, for example particularly upward, but, for example, may also have an isotropic emission characteristic. The light area can therefore also be seen well when viewed from the side with the LED lamp switched on, if the LED lamp emits in a narrow solid angle (for example upward). This is because, when viewed at an angle outside this solid angle (for example from the side), the viewer does not see any light from the headlight. The light device may, however, be seen if the light emits over a wider solid angle. In this case, there is no need for a phosphorescent substance. In general, the phosphorescent substance is also not essential, but may be advantageous depending on the type of use. If the coupling means is arranged in the beam path between the LED chip or chips and the conversion reflector, the light device can emit blue light. Furthermore, a phosphorescent substance on the light area need not itself be in a desired form; alternatively, the light device could also be painted black with cutouts, for example with cutouts in the form of a logo, from which light emerges.

In a further alternative embodiment, the further reflector 9 The reflector may likewise be coated with a fluorescent substance. This makes it possible to reduce the mutual absorption which is present in a fluorescent substance mixture. Depending on the LED wavelength, fluorescent substances with a white body color are also used, and are particularly suitable for the coating of the reflector 9.

### LIST OF REFERENCE SYMBOLS

1 LED module
2 Light-emitting diode
3 Substrate
4 Conversion reflector
4a Lower face of the conversion reflector
5 Foot
6a Facet
6b Facet
6c Facet
7 LED lamp
8 Bulb
9 Further reflector
10 LED lamp
11 Panel
12 LED lamp
13 Conversion reflector
14 Cover plate
15 LED lamp
16 Light device
17 Coupling means
18 Light area
19 Symbol
20 LED module
21 Annular substrate

1. An LED lighting device, comprising:
at least one light-emitting diode and at least one conversion reflector,
wherein the conversion reflector is configured to emit at least a portion of light emitted from the light-emitting diode at a converted wavelength, and wherein the conversion reflector covers the at least one light-emitting diode.

2. (canceled)

3. (canceled)

4. (canceled)

5. The LED lighting device as claimed in claim 34,
wherein the conversion reflector has a conversion layer in which the at least one wavelength-conversion material is embedded in an embedding material which scatters the light emitted from the at least one light-emitting diode.

6. (canceled)

7. The LED lighting device as claimed in claim 1,
wherein the light emitted from the conversion reflector results in a white mixed light;
wherein the light-emitting diode is a blue-emitting light-emitting diode, and the at least one wavelength-conversion material converts blue light to yellow light, or to yellow light and red light.

8. (canceled)

9. (canceled)

10. The LED lighting device as claimed in claim 1,
wherein a reflector area of the conversion reflector cannot be seen from the outside, at least in plan view.

11. The LED lighting device as claimed in claim 10,
wherein the reflector area of the conversion reflector cannot be seen from the outside.

12. The LED lighting device as claimed in claim 10,
wherein vision protection panels are provided and are arranged such that they prevent direct viewing of the reflector area of the conversion reflector.

13. The LED lighting device as claimed in claim 1,
wherein the conversion reflector is fitted to a substrate, to which the at least one light-emitting diode is fitted, in the emission direction of the at least one light-emitting diode.

14. The LED lighting device as claimed in claim 1,
wherein that the conversion reflector is arranged without direct contact with a supporting substrate in the emission direction of the at least one light-emitting diode.

15. The LED lighting device as claimed in claim 1, further comprising:
an LED module with a plurality of light-emitting diodes which are fitted on a common substrate, wherein the conversion reflector tapers in the direction of the LED module.

16. (canceled)

17. (canceled)

18. The LED lighting device as claimed in claim 1, further comprising:
a panel for blocking the light which is emitted from the light-emitting diode and does not fall on the conversion reflector.

19. The LED lighting device as claimed in claim 1, further comprising:
a further reflector, on which mixed light emitted from the conversion reflector falls.

20. (canceled)

21. The LED lighting device as claimed in claim 19,
wherein the further reflector is arranged at the side of the at least one light-emitting diode.

22. The LED lighting device as claimed in claim 1, further comprising:
a light device with a coupling means which inputs light emitted from the conversion reflector and leads it to a light area.

23. The LED lighting device as claimed in claim 22,
wherein the light area has a phosphorescent substance or a mask.

24. The LED lighting device as claimed in claim 22,
wherein the light area is arranged on a side of the conversion reflector facing away from the light-emitting diodes.

25. The LED lighting device as claimed in claim 1,
wherein at least one of the conversion reflector and the further reflector is facetted.

26. The LED lighting device as claimed in claim 25, further comprising:
a plurality of light-emitting diodes,
wherein the conversion reflector has at least as many facets as light-emitting diodes, and light from a light-emitting diode is reflected by means of at least one respectively associated facet.

27. The LED lighting device as claimed in claim 1, further comprising:
a bulb, which is transmissive for the light reflected from the conversion reflector.

28. (canceled)

29. The LED lighting device as claimed in claim 27,
wherein the further reflector is formed on the bulb.

30. The LED lighting device as claimed in claim 29,
wherein the further reflector is in the form of a diffusely scattering reflector.

31. The LED lighting device as claimed in claim 19,
wherein the further reflector is provided with a fluorescent layer.

32. The LED lighting device as claimed in claim 14, further comprising:
a cover plate, to which the conversion reflector is fitted.

33. The LED lighting device as claimed in claim 1,
wherein the LED lighting device corresponds to a retrofit lamp.

34. The LED lighting device as claimed in claim 1,
wherein the conversion reflector projects over the at least one light-emitting diode at the side.
